(19) United States
(12) Patent Application Publication
(10) Pub. No.: US 2019/0066947 A1
(43) Pub. Date: Feb. 28, 2019

(54) KEYBOARD KEY STRUCTURE

(71) Applicant: ASUSTeK COMPUTER INC., TAIPEI (TW)

(72) Inventor: Chien-Hsing CHIU, TAIPEI (TW)

(21) Appl. No.: 16/114,317

(22) Filed: Aug. 28, 2018

(30) Foreign Application Priority Data
Aug. 30, 2017 (TW) 106129575

(51) Int. Cl. H01H 13/83; H01H 13/705; H01H 13/14; H01H 13/02

(52) U.S. Cl. CPC H01H 13/83; H01H 13/705; H01H 13/14; H01H 13/023; H03K 2217/9653; H01H 2219/036; H01H 2219/062; H01H 2223/03; H01H 2219/03

(57) ABSTRACT

The disclosure discloses a keyboard key structure. The keyboard key structure includes a switch circuit board, a first luminescent circuit layer, a switch element, and a keycap. The first luminescent circuit layer is disposed on the switch circuit board, and includes a plurality of miniature light emitting diodes. The switch element passes through the first luminescent circuit layer and is configured to contact the switch circuit board. Two of the plurality of miniature light emitting diodes are respectively located on two opposite sides of the switch element. The keycap is connected to the switch element and covers the plurality of miniature light emitting diodes. The keycap further has at least one light transmissive portion.

### CROSS-REFERENCE TO RELATED APPLICATION

This application claims the priority benefit of TW application serial No. 106129575, filed on Aug. 30, 2017. The entirety of the above-mentioned patent application is hereby incorporated by reference herein and made a part of the specification.

### BACKGROUND OF THE INVENTION

### Field of the Invention

The disclosure relates to a keyboard key structure, and more particularly, to a keyboard key structure.

### Description of the Related Art

Generally speaking, since a structural configuration of a luminescent keyboard key provides uniform light beam, a polarization problem sometimes occurred which results poor user experience.

### BRIEF SUMMARY OF THE INVENTION

According to one aspect of the disclosure, a keyboard key structure is provided. The keyboard key structure includes a switch circuit board, a first luminescent circuit layer, a switch element, and a keycap. The first luminescent circuit layer is disposed on the switch circuit board, and includes a plurality of miniature light emitting diodes. The switch element passes through the first luminescent circuit layer and is configured to contact the switch circuit board. Two of the plurality of miniature light emitting diodes on the first luminescent circuit layer are respectively located on two opposite sides of the switch element. The keycap is connected to the switch element, covers the plurality of miniature light emitting diodes on the first luminescent circuit layer, and has at least one light transmissive portion.

### BRIEF DESCRIPTION OF THE DRAWINGS

FIG. 1 is a three-dimensional diagram of a keyboard key structure according to an embodiment of the disclosure;

FIG. 2 is a top view of the keyboard key structure in FIG. 1 with a keycap omitted;

FIG. 3 is a cross-sectional view of a structure in FIG. 2 along a line segment 2-2;

FIG. 4 is a three-dimensional diagram of a keyboard key structure according to another embodiment of the disclosure; and

FIG. 5 is a cross-sectional view of a structure in FIG. 4 along a line segment 4-4.

### DETAILED DESCRIPTION OF THE EMBODIMENTS

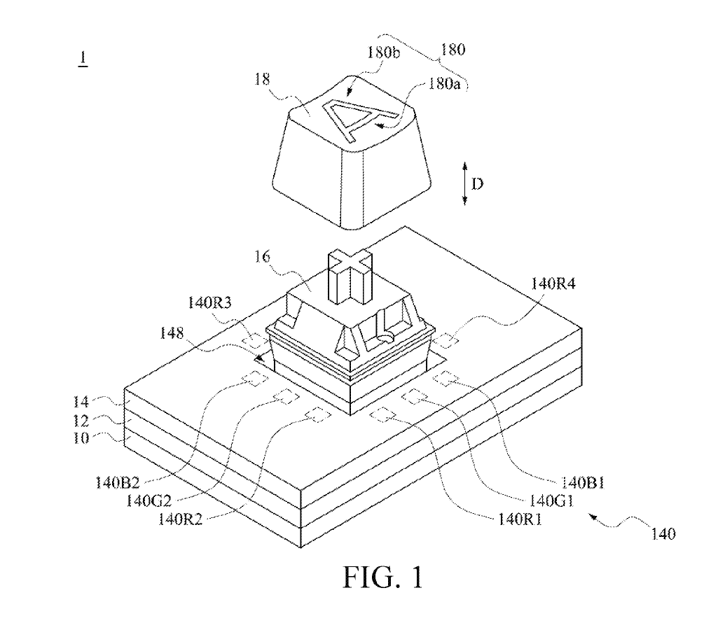

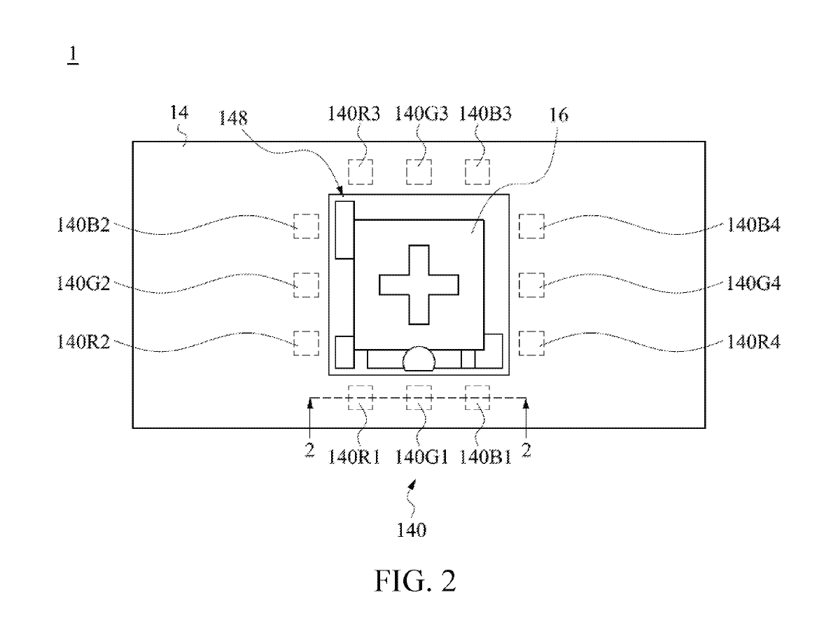

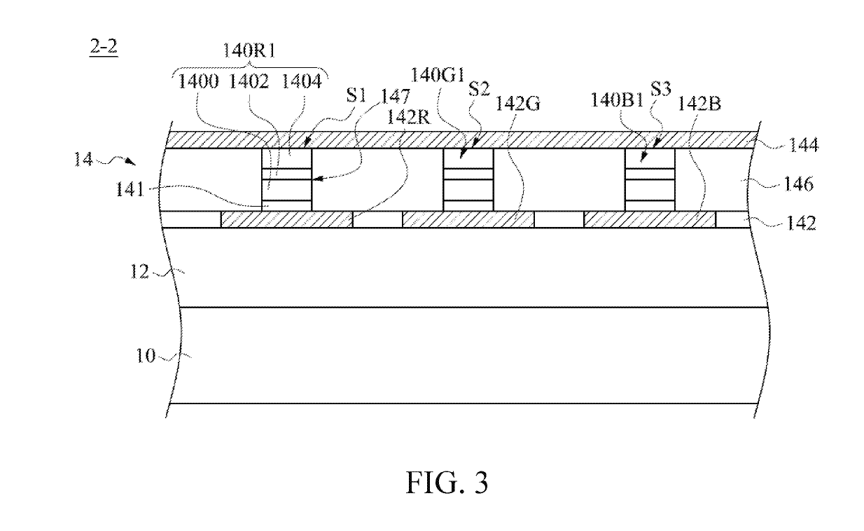

Refer to FIG. 1, FIG. 2, and FIG. 3. FIG. 1 is a three-dimensional diagram of a keyboard key structure 1 according to an embodiment of the disclosure. FIG. 2 is a top view of the keyboard key structure 1 in FIG. 1. For ease of understanding of the disclosure, a keycap 18 in FIG. 1 is omitted in FIG. 2. FIG. 3 is a cross-sectional view of a structure in FIG. 2 along a line segment 2-2. As shown in FIG. 1 to FIG. 3, in an embodiment, the keyboard key structure 1 includes a support plate 10, a switch circuit board 12, a luminescent circuit layer 14, a switch element 16, and the keycap 18 sequentially from the bottom to the top.

In this embodiment, the support plate 10 is made of a metal material and is configured to carry the switch circuit board 12, the luminescent circuit layer 14, the switch element 16, and the keycap 18. The switch circuit board 12 is disposed on the support plate 10, and is configured to conduct electricity when pressed by the switch element 16 in a direction D, and transmits a signal. The direction D mentioned above is substantially perpendicular to a surface of the switch circuit board 12 away from the support plate 10.

As shown in FIG. 1 to FIG. 3, the luminescent circuit layer 14 in this embodiment is disposed on the switch circuit board 12 and is removable. Furthermore, the luminescent circuit layer 14 includes a plurality of miniature light emitting diodes 140, an electrical adhesive layer 141, a drive electrode layer 142, a common electrode 144, and an insulating layer 146 shown in FIG. 3, and a through hole 148 (shown in FIG. 1). The size of the miniature light emitting diode 140 is at a micron grade. More specifically, the size of a side of the miniature light emitting diode 140 is between about 1 μm and about 150 μm. However, it is to be understood that, the disclosure is not limited to the size mentioned above, and in some embodiments, a larger or smaller dimension is applied.

The miniature light emitting diodes 140 on the luminescent circuit layer 14 in this embodiment include a plurality of first miniature light emitting diodes, a plurality of second miniature light emitting diodes, and a plurality of third miniature light emitting diodes. In this embodiment, the first miniature light emitting diodes 140R1, 140R2, 140R3, and 140R4 emit red light. The second miniature light emitting diodes 140G1, 140G2, 140G3, and 140G4 emits green light. The third miniature light emitting diodes 140B1, 140B2, 140B3, and 140B4 emit blue light. However, the quantity of the light emitting diodes in this embodiment is not limited herein.

As shown in FIG. 3, each miniature light emitting diode 140 in this embodiment includes a first type semiconductor layer 1400 (in an embodiment, a p-doped layer), an active layer 1402, and a second type semiconductor layer 1404 (in an embodiment, an n-doped layer). Although the first type semiconductor layer, the active layer, and the second type semiconductor layer are only marked with the red light miniature light emitting diode 140R1 in FIG. 3, it is to be understood that, other miniature light emitting diodes such as the green light miniature light emitting diodes 140G1, 140G2, 140G3, and 140G4, or the blue light miniature light emitting diodes 140B1, 140B2, 140B3, and 140B4 also have the same structure and respectively emit green light or blue light (that is, the first, the second, and third miniature light emitting diodes emit different color light). In this embodiment, the active layer 1402 of the miniature light emitting diode 140 is disposed on the first type semiconductor layer 1400 and the second type semiconductor layer 1404 is disposed on the active layer 1402.

In some embodiments, a combination of the first type semiconductor layer 1400, the active layer 1402, and the second type semiconductor layer 1404 is a columnar body with at least two opposite surfaces. In an embodiment, the combination of the first type semiconductor layer 1400, the active layer 1402, and the second type semiconductor layer 1404 is a cylinder, a multi-dimensional columnar body, or a trapezoidal columnar body. In this embodiment, a light emitting surface S1 of the second type semiconductor layer 1404 is opposite to the surface of the second type semiconductor layer 1404 which contacts the active layer 1402. Similarly, the second type semiconductor layers 1404 of the green light miniature light emitting diode 140G and the blue light miniature light emitting diode 140B also have a light emitting surface S2 and a light emitting surface S3 respectively.

In some embodiments, the miniature light emitting diodes 140 are formed on a growth substrate (not shown). Specifically, a block light emitting diode substrate on the growth substrate is processed to form an array of miniature light emitting diodes 140. The miniature light emitting diodes 140 are picked up from the growth substrate by using a micro-mechanical device in an individual form, in a group form, or in an array form, and transferred onto the drive electrode layer 142 of the luminescent circuit layer 14, but the disclosure is not limited thereto.

In some embodiments, the materials of the first type semiconductor layer 1400 include p-doped GaN or p-doped AlGaInP, and the materials of the second type semiconductor layer 1404 include n-doped GaN:Si. However, the disclosure is not limited to the materials mentioned above. The configuration manners of the active layer 1402 include p-n junction, various single quantum wells (SQW), or various multiple quantum wells (MQW). In an embodiment, the active layer 1402 is omitted and the second type semiconductor layer 1404 is directly connected to the first type semiconductor layer 1400. In an embodiment, the first type semiconductor layer 1400, the second type semiconductor layer 1404, and the active layer 1402 are formed by an epitaxy process or a metalorganic chemical vapor deposition (MOCVD) process.

As shown in FIG. 3, the drive electrode layer 142 of the luminescent circuit layer 14 is located on the switch circuit board 12. The drive electrode layer 142 includes a first drive electrode, a second drive electrode and a third drive electrode. In this embodiment, the first drive electrode is a red light drive electrode 142R, the second drive electrode is a green light drive electrode 142G, and the third drive electrode is a blue light drive electrode 142B.

The red light drive electrode 142R in the luminescent circuit layer 14 is electrically connected to the red light miniature light emitting diodes 140R1, 140R2, 140R3, and 140R4 and drives the red light miniature light emitting diodes 140R1, 140R2, 140R3, and 140R4 to emit red light. The green light drive electrode 142G is electrically connected to the green light miniature light emitting diodes 140G1, 140G2, 140G3, and 140G4 and drives the green light miniature light emitting diodes 140G1, 140G2, 140G3, and 140G4 to emit green light. The blue light drive electrode 142B is electrically connected to the blue light miniature light emitting diodes 140B1, 140B2, 140B3, and 140B4 and drives the blue miniature light emitting diodes 140B1, 140B2, 140B3, and 140B4 to emit blue light. Furthermore, the red light drive electrode 142R, the green light drive electrode 142G; and the blue light drive electrode 142B of the luminescent circuit layer 14 are electrically separated from one another.

Therefore, according to an actual demand in use, the red light drive electrode 142R, the green light drive electrode 142G, and the blue light drive electrode 142B are driven separately to control the red light miniature light emitting diodes 140R1, 140R2, 140R3, and 140R4, the green light miniature light emitting diodes 140G1, 140G2, 140G3, and 140G4, and the blue light miniature light emitting diodes 140B1, 140B2, 140B3, and 140B4 to emit light respectively.

The insulating layer 146 in this embodiment is located on the drive electrode layer 142 and has a plurality of openings 147 (only one is exemplarily shown in FIG. 3) for exposing one part of the red light drive electrode 142R, one part of the green light drive electrode 142G, and one part of the blue light drive electrode 142B respectively. The red light miniature light emitting diode 140R1, the green light miniature light emitting diode 140G1, and the blue light miniature light emitting diode 140B1 are respectively embedded into the openings 147 of the insulating layer 146 and are electrically connected to the red light drive electrode 142R, the green light drive electrode 142G, and the blue light drive electrode 142B respectively through the first type semiconductor layer 1400 and the electrical adhesive layer 141.

The common electrode 144 in this embodiment is electrically connected to the second type semiconductor layers 1404 of the miniature light emitting diodes 140. The first type semiconductor layers 1400, the active layers 1402, and the second type semiconductor layers 1404 are disposed between the drive electrode layer 142 and the common electrode 144. Furthermore, the common electrode 144 in this embodiment entirely contacts the second type semiconductor layers 1404, but the disclosure is not limited thereto. In some embodiments, the common electrode 144 is presented in a form of a bonding wire and partially electrically contacts the second type semiconductor layers 1404.

In this embodiment, the red light drive electrode 142R, the green light drive electrode 142G, the blue light drive electrode 142B, and the common electrode 144 of the luminescent circuit layer 14 are made of conductive materials. In an embodiment, the materials of the red light drive electrode 142R, the green light drive electrode 142G, the blue light drive electrode 142B, and the common electrode 144 include non-transparent conductive materials (such as Ag, Al, Cu, Mg, or Mo), transparent conductive materials (such as indium tin oxide, indium zinc oxide or aluminum zinc oxide), a composite layer or an alloy of the materials mentioned above, but the disclosure is not limited thereto. The red light drive electrode 142R, the green light drive electrode 142G, and the blue light drive electrode 142B in this embodiment have reliable conductivity and light reflectivity.

The electrical adhesive layer 141 in this embodiment is disposed in the opening 147 to fix the miniature light emitting diodes 140 and is electrically connected to the drive electrode layer 142. In this embodiment, the electrical adhesive layer 141 is a conductive adhesive or another suitable conductive material, such as In, Bi, Sn, Ag, Au, Cu, Ga, and Sb, but the disclosure is not limited by the materials mentioned above.

As shown in FIG. 1 and FIG. 2, the switch element 16 in this embodiment passes through the luminescent circuit layer 14 via the through hole 148 to contact the switch circuit board 12. In this embodiment, the switch element 16 is a mechanical shaft switch element, but the disclosure is not limited thereto. Two of the plurality of miniature light emitting diodes 140 of the luminescent circuit layer 14 are respectively located on two opposite sides of the switch element 16. In an embodiment, the red light miniature light emitting diode 140R1 and the red light miniature light emitting diode 140R3 are respectively located on two opposite sides (that is, the upper and lower sides in FIG. 2) of the switch element 16. Relatively, the red light miniature light emitting diode 140R2 and the red light miniature light emitting diode 140R4 in this embodiment are respectively located on other two opposite sides (that is, the left and right sides in FIG. 2) of the switch element 16.

Furthermore, the green light miniature light emitting diode 140G1 and the green light miniature light emitting diode 140G3 are also located on the two opposite sides (that is, the upper and lower sides in FIG. 2), on which the red light miniature light emitting diode 140R1 and the red light miniature light emitting diode 140R3 are located, of the switch element 16. Relatively, the green light miniature light emitting diode 140G2 and the green light miniature light emitting diode 140G4 in this embodiment are located on the other two sides (that is, the left and right sides in FIG. 2) of the switch element 16. Similarly, the blue light miniature light emitting diode 140B1 and the blue light miniature light emitting diode 140B3 are located on the two opposite sides (that is, the upper and lower sides in FIG. 2) of the switch element 16. Relatively, the blue light miniature light emitting diode 140B2 and the blue light miniature light emitting diode 140B4 in this embodiment are located on the other two sides (that is, the left and right sides in FIG. 2) of the switch element 16.

As shown in FIG. 1 and FIG. 2, the keycap 18 is connected to the switch element 16. The keycap 18 covers the plurality of miniature light emitting diodes 140 in the luminescent circuit layer 14 and has at least one light transmissive portion 180. In this embodiment, the miniature light emitting diodes 140 in the luminescent circuit layer 14 are electrically coupled to the drive electrode layer 142 to receive the electric power provided by the drive electrode layer 142, and the active layers 1402 of the miniature light emitting diodes 140 emit color light. The color light passes through the first type semiconductor layer 1400 (see FIG. 3) and the common electrode 144 (see FIG. 3) to reach the keycap 18 and passes through the light transmissive portion 180 of the keycap 18 to enable the keyboard key structure 1 to emit color light.

Furthermore, the light transmissive portion 180 in this embodiment includes a first part 180a and a second part 180b. The first part 180a of the light transmissive portion 180 is located on one side close to the red light miniature light emitting diode 140R1, and the second part 180b is located on one side close to the red light miniature light emitting diode 140R3. The red light emitted by the red light miniature light emitting diode 140R1 passes through the first part 180a of the light transmissive portion 180. Since the red light emitted by the red light miniature light emitting diode 140R1 is blocked by the switch element 16, the red light cannot reach the second part 180b of the light transmissive portion 180. Furthermore, the second part 180b is unable to provide light to emit red light. However, in this embodiment, the red light emitted by the red light miniature light emitting diode 140R3 located on an opposite side of the switch element 16 passes through the second part 180b of the light transmissive portion 180, therefore to compensate lack of light.

Therefore, the structural configuration in this embodiment enables the light transmissive portion 180 to evenly emit light to prevent the light transmissive portion 180 of the keycap 18 from generating polarized light. The light emitting effect of the light transmissive portion 180 is improved and a situation that a user presses a wrong key because the gloomy of the keycap 18 with signature is avoid. Therefore, the user operates the keyboard key structure 1 more accurately. Furthermore, the keyboard key structure 1 in this embodiment includes the luminescent circuit layer 14 and the miniature light emitting diodes 140. Therefore, sufficient light is provided in a limited space through the plurality of miniature light emitting diodes 140, and the miniature light emitting diodes 140 are flexibly configured in positions in the keyboard key structure 1.

Furthermore, when a miniature light emitting diode 140 on the luminescent circuit layer 14 is damaged, only the luminescent circuit layer 14 needs to be substituted, thereby reducing the time of maintaining the keyboard key structure 1.

Furthermore, the keyboard key structure 1 in this embodiment includes the miniature light emitting diodes 140 with different light color. Therefore, a plurality of keyboard key structures 1 emit different color light through the miniature light emitting diodes 140 with different color or mixed color thereof, thereby different color representing different functional areas on the keyboard (not shown) is set by users. Accordingly, users are able to operate the areas in interest with specific functions on the keyboard rapidly that are defined by different light colors.

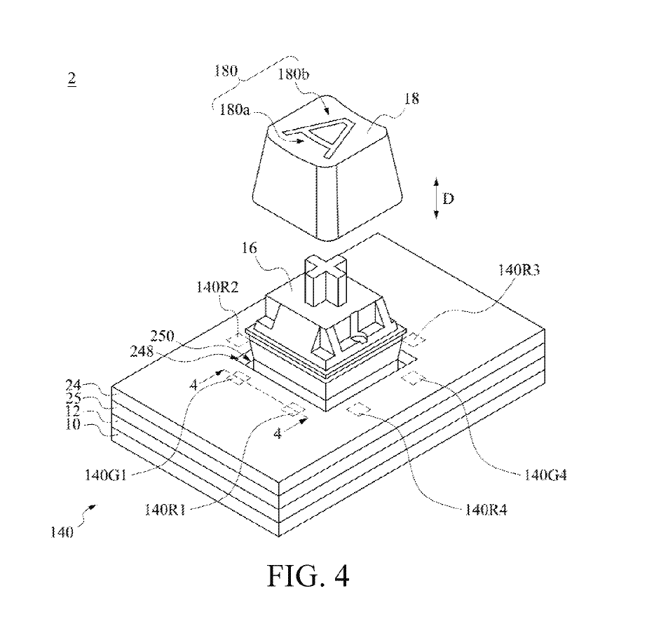

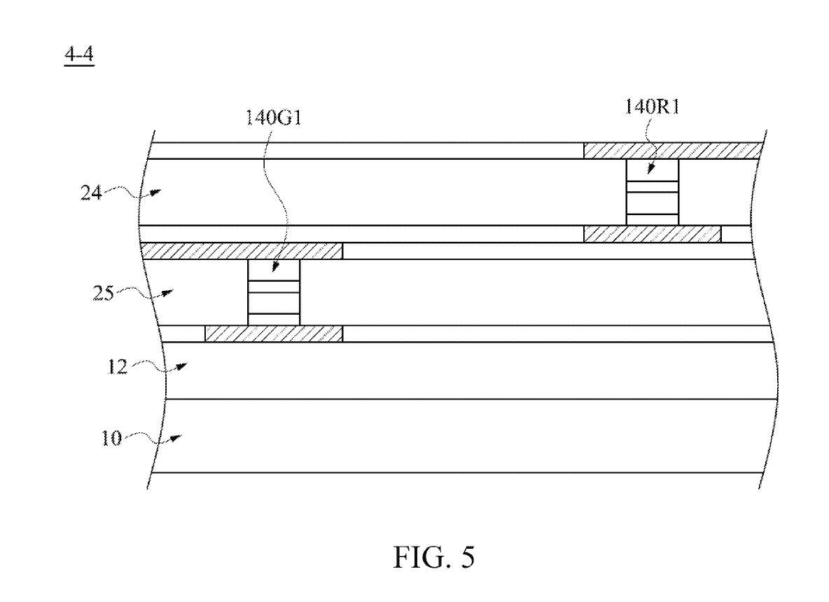

Refer to FIG. 4 and FIG. 5. FIG. 4 is a three-dimensional diagram of a keyboard key structure 2 according to another embodiment of the disclosure. FIG. 5 is a cross-sectional view of a structure in FIG. 4 along a line segment 4-4. As shown in FIG. 4 and FIG. 5, the keyboard key structure 2 in this embodiment includes a support plate 10, a switch circuit board 12, a first luminescent circuit layer 24, a second luminescent circuit layer 25, a switch element 16, and a keycap 18. The structures and the functions of the elements and the connecting relationship of the elements are all substantially the same as those of the keyboard key structure 1 in FIG. 1 to FIG. 3, and can be known according to the description mentioned above, and will not be described repeatedly herein.

It should be noted herein that, this embodiment is different from the embodiment in FIG. 1 to FIG. 3 in that, in this embodiment, the keyboard key structure 2 further includes the second luminescent circuit layer 25.

As shown in FIG. 4 and FIG. 5, the plurality of miniature light emitting diodes 140 in the first luminescent circuit layer 24 are red light miniature light emitting diodes 140R1, 140R2, 140R3, and 140R4, and the first luminescent circuit layer 24 has a first through hole 248. The second luminescent circuit layer 25 is disposed between the switch circuit board 12 and the first luminescent circuit layer 24. The second luminescent circuit layer 25 includes green light miniature light emitting diodes 140G1 and 140G4 (furthermore, the second luminescent circuit layer 25 further includes two green light miniature light emitting diodes (not shown) on other two opposite sides of the switch element 16 in FIG. 4) and a second through hole 250. The switch element 16 passes through the first through hole 248 of the first luminescent circuit layer 24 and the second through hole 250 of the second luminescent circuit layer 25.

The first luminescent circuit layer 24 and the second luminescent circuit layer 25 in this embodiment are both removable. Therefore, the configuration of the first luminescent circuit layer 24 or the second luminescent circuit layer 25 is adjustable according to an actual demand. Furthermore, when a miniature light emitting diode 140 in the first luminescent circuit layer 24 or the second luminescent circuit layer 25 is damaged, only the first luminescent circuit layer 24 or the second luminescent circuit layer 25 needs to be substituted, thereby reducing the time of maintaining the keyboard key structure 2.

In this embodiment, a vertical projection of the red light miniature light emitting diodes 140R1, 140R2, 140R3, and 140R4 in the first luminescent circuit layer 24 on the switch circuit board 12 does not overlap a vertical projection of the green light miniature light emitting diodes 140G1 and 140G4 in the second luminescent circuit layer 25 on the switch circuit board 12. The structural configuration disclosed herein reduces interference of the light beams emitted by the miniature light emitting diodes 140 of different color light, so that the first luminescent circuit layer 24 and the second luminescent circuit layer 25 of the keyboard key structure 2 improves the luminescent efficiency.

According to the detailed description of the embodiments of the disclosure, it can be obviously seen that, two of a plurality of miniature light emitting diodes in this embodiment are located on two opposite sides of the switch element respectively, and therefore, the emitted color light reaches the first part and the second part of the light transmissive portion on the keycap. Hence, the structural configuration disclosed herein enables the light transmissive portion on the keycap to uniformly emit light to avoid generating polarized light. And the luminescent effect of the light transmissive portion is improved and avoids a wrong key being pressed when the user cannot recognize the position of the keycap, and therefore, the user can operate the keyboard key structure accurately. Furthermore, the luminescent circuit layer in this embodiment is removable. Therefore, when a miniature light emitting diode in the luminescent circuit layer is damaged, only the luminescent circuit layer needs to be substituted, thereby reducing the time of maintaining the keyboard key structure.

Although the embodiments of the disclosure are disclosed above, the embodiments are not intended to limit the disclosure. A person of ordinary skill in the art can make some changes and modifications without departing from the spirit and scope of the disclosure. The protection scope of the disclosure should be subject to the claims.

What is claimed is:

1. A keyboard key structure, comprising:
a switch circuit board;
a first luminescent circuit layer, disposed on the switch circuit board, and comprising a plurality of miniature light emitting diodes;
a switch element, passing through the first luminescent circuit layer, and configured to contact the switch circuit board, two of the miniature light emitting diodes being respectively located on two opposite sides of the switch element; and
a keycap, connected to the switch element, covering the miniature light emitting diodes, and having at least one light transmissive portion.

2. The keyboard key structure according to claim 1, wherein the first luminescent circuit layer has a through hole, and the switch element passes through the through hole to contact the switch circuit board.

3. The keyboard key structure according to claim 1, wherein the switch element is a mechanical shaft switch element.

4. The keyboard key structure according to claim 1, wherein the miniature light emitting diodes comprise a plurality of first miniature light emitting diodes and a plurality of second miniature light emitting diodes, and a color light emitted by the first miniature light emitting diodes is different from that emitted by the second miniature light emitting diodes.

5. The keyboard key structure according to claim 4, wherein the color light emitted by the first miniature light emitting diodes or the second miniature light emitting diodes is red light, green light, or blue light.

6. The keyboard key structure according to claim 4, wherein two of the first miniature light emitting diodes are respectively located on two opposite sides of the switch element, and two of the second miniature light emitting diodes are respectively located on the two opposite sides of the switch element.

7. The keyboard key structure according to claim 4, wherein two of the first miniature light emitting diodes are respectively located on two opposite sides of the switch element, and two of the second miniature light emitting diodes are respectively located on other two opposite sides of the switch element.

8. The keyboard key structure according to claim 4, wherein the first luminescent circuit layer further comprises a first drive electrode and a second drive electrode, the first drive electrode is electrically connected to the first miniature light emitting diodes, the second drive electrode is electrically connected to the second miniature light emitting diodes, and the first drive electrode is electrically separated from the second drive electrode.

9. The keyboard key structure according to claim 1, wherein the miniature light emitting diodes are a plurality of first miniature light emitting diodes, and the keyboard key structure further comprises:
a second luminescent circuit layer, disposed between the switch circuit board and the first luminescent circuit layer, and comprising a plurality of second miniature light emitting diodes, wherein
the switch element passes through the first luminescent circuit layer and the second luminescent circuit layer, and a color light emitted by the first miniature light emitting diodes is different from that emitted by the second miniature light emitting diodes.

10. The keyboard key structure according to claim 9, wherein a vertical projection of the first miniature light emitting diodes on the switch circuit board does not overlap a vertical projection of the second miniature light emitting diodes on the switch circuit board.
